(19) United States
(12) Patent Application Publication
(10) Pub. No.: US 2007/0132055 A1
(43) Pub. Date: Jun. 14, 2007

(54) SEMICONDUCTOR DEVICE AND MANUFACTURING METHOD THEREOF

(76) Inventor: Hwal Pyo Kim, Incheon (KR)

Correspondence Address: SHERR & NOURSE, PLLC, 620 HERNDON PARKWAY, SUITE 200, HERNDON, VA, 20170, US

(21) Appl. No.: 11/610,441

(22) Filed: Dec. 13, 2006

(30) Foreign Application Priority Data
Dec. 14, 2005 (KR) 10-2005-0123323

(51) Int. Cl. H01L 29/00

(52) U.S. Cl. 257/506

(57) ABSTRACT

A semiconductor device may include at least one of: a semiconductor substrate having a conductive layer; an interlayer dielectric layer formed over a semiconductor substrate; a lower inter-metal dielectric (IMD) layer (e.g. having first and second contact holes) formed over an interlayer dielectric layer; a metal interconnection and a MIM lower electrode formed in first and second contact holes; an etching stop layer formed over a lower IMD layer and a metal interconnection; an upper IMD layer; a first trench formed over a MIM lower electrode; a second trench formed in an upper portion of a first trench over an etching stop layer; a dielectric substance formed over the internal walls of the first and second trenches; and a MIM upper electrode formed over the dielectric substance in a first trench.

The present application claims priority under 35 U.S.C. 119 and 35 U.S.C. 365 to Korean Patent Application No. 10-2005-0123323 (filed on Dec. 14, 2005), which is hereby incorporated by reference in its entirety.

### BACKGROUND

Capacitors in semiconductor devices may be poly-insulator-poly (PIP) capacitors, metal-insulator-poly (MIP) capacitors, and/or metal insulator metal (MIM) capacitors. A PIP capacitor may include an insulator between metal and polysilicon. A MIM capacitor may include an insulator between metal and metal. A capacitor may be classified according to materials that form the capacitor.

Capacitors may consume large areas, which may allow a capacitor to operate at high speed. For example, in a MIM capacitor, a pre-metal dielectric (PMD) layer may be formed over a semiconductor substrate and a lower insulating layer (e.g. having first and second contact holes) may be formed over the PMD layer.

A metal interconnection and a lower electrode may be formed by filling first and second contact holes with metal. An etching stop layer and an upper insulating layer may be formed oover the entire surface of the upper structure of a semiconductor substrate. A trench may be formed by patterning an upper insulating layer. A dielectric substance may be formed over an upper insulating layer having a trench. Metal may be formed over a dielectric substance and chemical mechanical polishing (CMP) may be performed for planarization to form an upper electrode. A cleaning process may remove residue from an upper electrode.

Metal may be laminated over a dielectric substance to have a thickness equal to or smaller than the thickness of an upper insulating layer. To reduce costs, an upper electrode maybe formed such that an upper electrode is lower than an upper insulating layer.

If an upper electrode is lower than an upper insulating layer, there may be a step difference between the upper insulating layer and the upper electrode. A step difference may complicate removal of residue on an upper electrode through a cleaning process. If residue is not removed, electrical characteristics and reliability of a semiconductor device may be degraded.

### SUMMARY

Embodiments relate to a semiconductor device and/or a method of manufacturing a semiconductor device. Embodiments relate to a method of manufacturing a capacitor. Embodiments relate to a semiconductor device with residue on an upper electrode substantially removed. Embodiments may improve electrical characteristics and reliability of a semiconductor device.

In embodiments, a semiconductor device may include at least one of: a semiconductor substrate having a conductive layer; an interlayer dielectric layer formed over a semiconductor substrate; a lower inter-metal dielectric (IMD) layer (e.g. having first and second contact holes) formed over an interlayer dielectric layer; a metal interconnection and a MIM lower electrode formed in first and second contact holes; an etching stop layer formed over a lower IMD layer and a metal interconnection; an upper IMD layer; a first trench formed over a MIM lower electrode; a second trench formed in an upper portion of a first trench over an etching stop layer; a dielectric substance formed over the internal walls of the first and second trenches; and a MIM upper electrode formed over the dielectric substance in a first trench. A width of a second trench may be larger than a width of a first trench. A depth of a second trench may be smaller than a depth of a first trench.

Embodiments relate to a method of manufacturing a semiconductor device. In embodiments, a method may include at least one of: forming an interlayer dielectric layer over a semiconductor substrate that includes a conductive layer; forming a lower inter-metal dielectric (IMD) layer (e.g. having first and second contact holes) over an interlayer dielectric layer; forming a metal interconnection and a MIM lower electrode in first and second contact holes; sequentially forming an etching stop layer and an upper IMD layer over an upper structure of a semiconductor substrate; patterning an upper IMD layer to form a first trench (e.g. over a MIM lower electrode) and a second trench (e.g. in an upper portion of the first trench); forming a dielectric substance over a surface of an upper structure of a semiconductor substrate; forming a metal thin layer over a dielectric substance; performing a CMP process on a surface of an upper structure of a semiconductor substrate to form a MIM upper electrode in a dielectric substance formed on a first trench; and cleaning a surface of an upper structure of a semiconductor substrate.

An upper IMD layer and an etching stop layer may be removed when forming a first and second trench. An etching stop layer may serve as an etching stop point when patterning an upper IMD layer. The width of a second trench may be larger than the width of a first trench. The depth of a second trench may be smaller than the depth of a first trench.

### BRIEF DESCRIPTION OF DRAWINGS

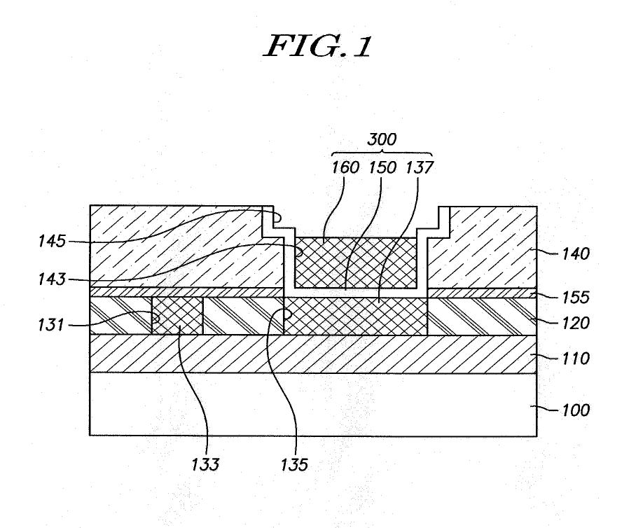

Example FIG. 1 illustrates a structure of a semiconductor device, according to embodiments.

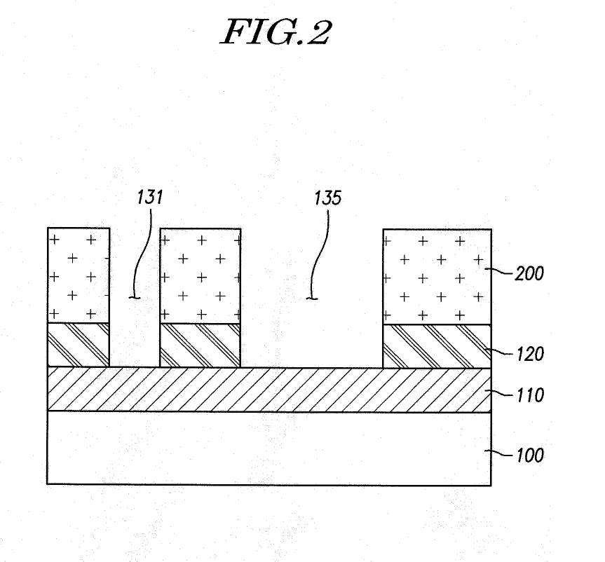

Example FIGS. 2 to 5 illustrate a method of manufacturing a semiconductor device, according to embodiments.

### DETAILED DESCRIPTION

Example FIG. 1 illustrates a structure of a semiconductor device according to embodiments. As illustrated in FIG. 1, interlayer dielectric layer 110 may be formed over semiconductor substrate 100. Semiconductor substrate 100 may include a conductive layer. Lower inter-metal dielectric (IMD) layer 120 may be formed over interlayer dielectric layer 110. Lower inter-metal dielectric (IMD) layer 120 may have first contact hole 131 and/or second contact hole 135. Metal interconnection 133 and lower electrode 137 may be formed in first contact hole 131 and/or second contact layer 135. Upper IMD layer 140 may be formed over etching stop layer 155. First trench 143 and/or second trench 145 maybe formed in upper IMD layer 140. In embodiments, first trench 143 and/or second trench 145 may be formed in the entire surface of an upper structure of semiconductor substrate 100. Dielectric substance 150 may be deposited over upper IMD layer 140 and lower electrode 137 inside first trench 143 and/or second trench 145. Upper electrode 160 may be formed over dielectric substance 150 in first trench 143. In embodiments, the width of second trench 145 may be larger than first trench 143. In embodiments, the depth of second trench 145 may be smaller than the depth of first trench 143.

Example FIGS. 2 to 5 illustrate processes of manufacturing a semiconductor device, according to embodiments. As illustrated in FIG. 2, interlayer dielectric layer 110 may formed over semiconductor substrate 100. Semiconductor substrate 100 may include a conductive layer. Lower IMD layer 120 and lower pattern photosensitive layer 200 may be sequentially formed over interlayer dielectric layer 110. Lower IMD insulating layer 120 may be patterned using lower pattern photosensitive layer 200 as a mask to form first contact hole 131 and/or second contact hole 135.

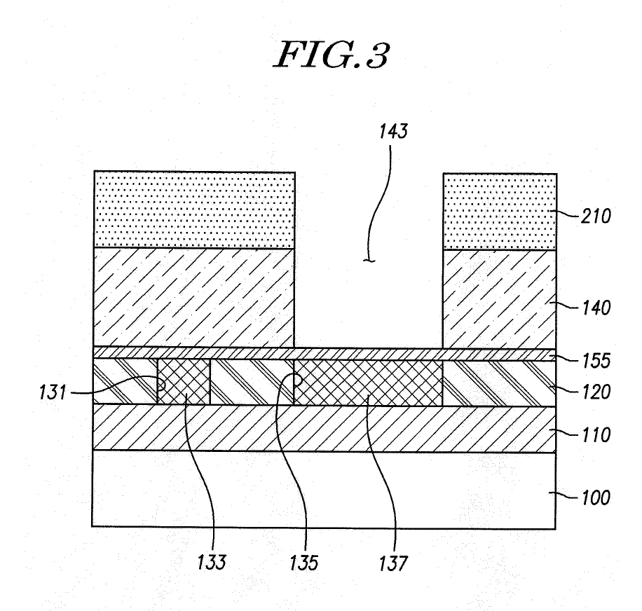

As illustrated in FIG. 3, lower pattern photosensitive layer 200 may be removed. First contact hole 131 and/or second contact hole 135 may be filled with metal to form metal interconnection 133 and lower electrode 137. Etching stop layer 155 may be formed over lower IMD layer 120, metal interconnection 133, and/or lower electrode 137. Upper IMD layer 140 and first upper photosensitive layer 210 may be sequentially formed over etching stop layer 155. Upper IMD layer 140 may be patterned using first upper photosensitive layer 210 as a mask to form first trench 143. First trench 143 may expose etching stop layer 155. Etching stop layer 155 may be an etching stop point of upper IMD layer 140.

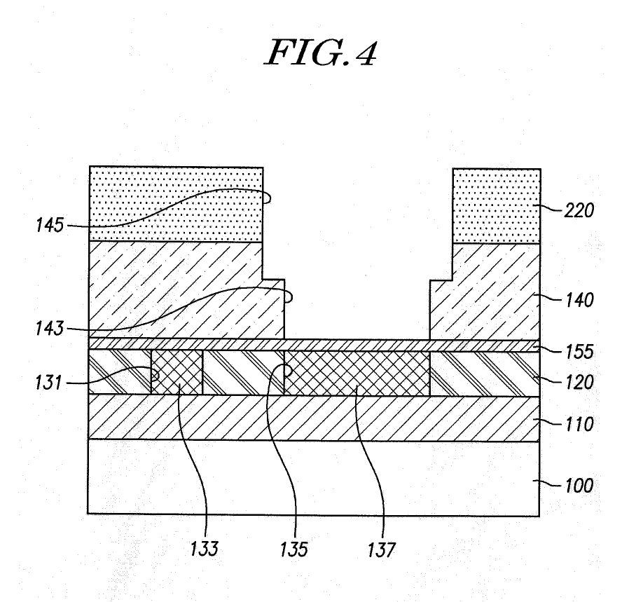

As illustrated in FIG. 4, first upper photosensitive layer 210 may be removed. Second upper photosensitive layer 220 may be formed over upper IMD layer 140. Upper IMD layer 140 may be patterned using second upper photosensitive layer 220 as a mask to form second trench 145. Second trench 145 may have a depth smaller than the depth of first trench 143. Second trench 145 may have a width larger than the width of first trench 143.

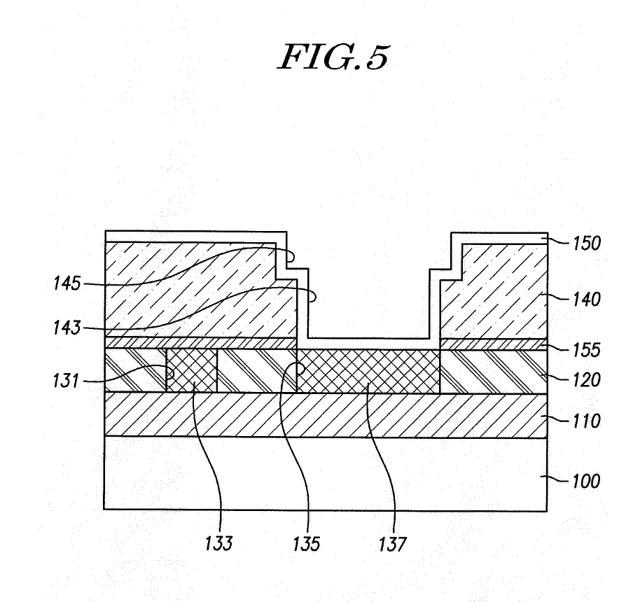

As illustrated in FIG. 5, etching stop layer 155 maybe exposed through second upper photosensitive layer 220 and first trench 143. Etching stop layer 155 may be removed to expose lower electrode 137. Dielectric substance 150 may be formed over upper IMD layer 140 and lower electrode 137.

As illustrated in FIG. 1, metal may be formed over dielectric substance 150. A CMP process may be performed to form upper electrode 160 that fills first trench 143. In embodiments, a MIM capacitor 300 may include upper electrode 160, dielectric substance 150, and lower electrode 137. A cleaning process may remove residue (not shown) on upper electrode 160.

Upper IMD layer 140 may have first trench 143 and second trench 145, according to embodiments. Due to having two trenches, the step difference between upper electrode 160 and upper IMD layer 140 may be smaller than if there is only one trench, according to embodiments. Due to having two trenches, the area of upper IMD layer 140 that exposes upper electrode 160 is larger than if there is only one trench, according to embodiments. In accordance with embodiments, it is possible to completely or substantially remove all the residue on upper electrode 160 during a cleaning process. In embodiments, it is possible to improve the electrical characteristic and the reliability of a semiconductor device.

It will be apparent to those skilled in the art that various modifications and variations can be made to embodiments. Thus, it is intended that embodiments cover modifications and variations thereof within the scope of the appended claims.

What is claimed:

1. A semiconductor device comprising:
a first dielectric layer formed over a semiconductor substrate;
a first trench formed in the first dielectric layer;
a second trench formed in the first dielectric layer above the first trench;
a dielectric substance formed over walls of the first trench and the second trench; and
an electrode formed in the first trench.

2. The semiconductor device of claim 1, wherein the electrode is an upper metal-insulator-metal electrode.

3. The semiconductor device of claim 1, wherein the first dielectric layer is a first inter-metal dieletric layer.

4. The semiconductor device of claim 1, wherein the first dielectric layer is formed over an etching stop layer.

5. The semiconductor device of claim 1, wherein the semiconductor substrate comprises a conductive layer.

6. The semiconductor device of claim 1, comprising an interlayer dielectric layer formed over the semiconductor substrate.

7. The semiconductor device of claim 1, comprising a second dielectric layer, wherein:
the second dielectric layer is a second inter-metal dielectric layer;
the first dielectric layer is formed above the second dielectric layer;
the second dielectric layer comprises at least one first contact hole and at least one second contact hole.

8. The semiconductor device of claim 7, wherein:
a metal interconnection is formed in the first contact hole; and
a lower metal-insulator-metal electrode is formed in the second contact hole.

9. The semiconductor device of claim 1, comprising an etching stop layer formed over the second dielectric layer.

10. The semiconductor device of claim 1, wherein a width of the second trench is larger than a width of the first trench.

11. The semiconductor device of claim 1, wherein a depth of the second trench is smaller than a depth of the first trench.

12. A method comprising:
forming a first dielectric layer a semiconductor substrate;
forming a first trench formed in the first dielectric layer;
forming a second trench in the first dielectric layer above the first trench;
forming a dielectric substance over walls of the first trench and the second trench; and
forming an electrode in the first trench.

13. The method of claim 12, comprising:
forming an interlayer dielectric layer over the semiconductor substrate, wherein the semiconductor substrate comprises a conductive layer;
forming a lower inter-metal dielectric layer over the interlayer dielectric layer;
forming a metal-insulator-metal lower electrode in the lower inter-metal dielectric layer;
forming an etching stop layer over the lower inter-metal dielectric layer, wherein the first dielectric layer is an upper inter-metal dielectric layer;
forming a metal thin layer on the dielectric substance;
performing chemical mechanical polishing over the upper inter-metal dielectric layer, wherein the electrode is a metal-insulator-metal upper electrode; and
performing a cleaning process.

14. The method of claim 13, wherein the upper inter-metal dielectric layer and the etching stop layer are removed during formation of the first trench and the second trench.

15. The method of claim 13, wherein the etching stop layer serves as an etching stop point during formation of the first trench.

16. The method of claim 13, wherein a width of the second trench is larger than a width of the first trench.

17. The method of claim 13, wherein a depth of the second trench is smaller than a depth of the first trench.

18. The method of claim 13, comprising forming a first contact hole and a second contact hole in the lower inter-metal dielectric layer, before forming the metal-insulator-metal lower electrode.

19. The method of claim 18, wherein said forming the metal-insulator-metal lower electrode, a metal interconnection is formed in the first contact hole and the metal-insulator-metal lower electrode is formed in the second contact hole.
